(19) United States
(12) Patent Application Publication
(10) Pub. No.: US 2014/0284637 A1
(43) Pub. Date: Sep. 25, 2014

(54) SEMICONDUCTOR LIGHT EMITTING DEVICE AND METHOD FOR MANUFACTURING SAME

(71) Applicant: KABUSHIKI KAISHA TOSHIBA, Minato-ku (JP)

(72) Inventors: Kazuhiro Akiyama, Kanagawa-ken (JP); Shuji Itonaga, Kanagawa-ken (JP)

(73) Assignee: KABUSHIKI KAISHA TOSHIBA, Minato-ku (JP)

(21) Appl. No.: 14/021,760

(22) Filed: Sep. 9, 2013

(30) Foreign Application Priority Data
Mar. 22, 2013 (JP) 2013-061139

(51) Int. Cl. H01L 33/22; H01L 33/32

(52) U.S. Cl. CPC H01L 33/22; H01L 33/32
USPC 257/95; 438/29

(57) ABSTRACT

According to one embodiment, a method for manufacturing a semiconductor light emitting device includes performing plasma processing of a stacked body. The stacked body has a first semiconductor layer and a second semiconductor layer provided on the first semiconductor layer. The plasma processing is performed on a surface of the stacked body where the second semiconductor layer is exposed such that the second semiconductor layer remains. The first semiconductor layer includes gallium and nitrogen. The second semiconductor layer includes aluminum and nitrogen. The method includes forming a plurality of protrusions by performing wet etching of the surface after the plasma processing is performed. At least a lower portion of the plurality of protrusions is made of the first semiconductor layer.

### CROSS-REFERENCE TO RELATED APPLICATIONS

This application is based upon and claims the benefit of priority from Japanese Patent Application No. 2013-061139, filed on Mar. 22, 2013; the entire contents of which are incorporated herein by reference.

### FIELD

Embodiments described herein relate generally to a semiconductor light emitting device and a method for manufacturing the same.

### BACKGROUND

In recent years, LEDs (Light Emitting Diodes) that use Group III nitride semiconductors have been developed. Such an LED is manufactured by, for example, forming a stacked body made of semiconductor layers such as a gallium nitride layer (GaN layer), etc., on a crystal growth substrate and subsequently removing the crystal growth substrate. Also, technology has been proposed in which a fine unevenness is formed to increase the light extraction efficiency by performing wet etching of the N-polar plane of the stacked body using an alkaline aqueous solution.

On the other hand, inexpensive silicon substrates have been studied to replace sapphire substrates as the crystal growth substrate. In such a case, because a solid solution undesirably forms between the GaN layer and the silicon substrate when the GaN layer is formed directly on the silicon substrate, an aluminum nitride layer (AlN layer) is formed on the silicon substrate; and the GaN layer is formed on the AlN layer. Then, an unevenness is formed in the AlN layer that is exposed by removing the silicon substrate. However, problems include a low wet etching rate of the AlN layer and difficulties forming the unevenness.

### BRIEF DESCRIPTION OF THE DRAWINGS

FIGS. 1A to 1F are cross-sectional views of processes, showing a method for manufacturing a semiconductor light emitting device according to a first embodiment;

FIG. 2 is a cross-sectional view showing the semiconductor light emitting device according to the first embodiment;

FIG. 3 shows the optical path inside the semiconductor light emitting device according to the first embodiment;

FIG. 4 is a cross-sectional view showing a semiconductor light emitting device according to a modification of the first embodiment;

FIGS. 5A to 5D are block diagrams showing a method for manufacturing the semiconductor light emitting device according to a second embodiment;

FIG. 6 is a plan view showing a resist mask that is formed in the second embodiment;

FIG. 7A is a plan view showing the semiconductor light emitting device according to the second embodiment; and FIG. 7B is a cross-sectional view along line A-A′ of FIG. 7A;

FIGS. 8A to 8E are surface SEM photographs showing each of the samples of a first test example;

FIG. 9 is a cross section SEM photograph showing sample No. 3;

FIGS. 10A to 10E show states of a sample of a second test example at each of the stages; and

FIG. 11 is a graph showing the effects of the fluctuation of the height of the protrusions on the light extraction efficiency of the semiconductor light emitting device, where the horizontal axis is the value of the difference d, and the vertical axis is the light extraction efficiency.

### DETAILED DESCRIPTION

In general, according to one embodiment, a method for manufacturing a semiconductor light emitting device includes performing plasma processing of a stacked body. The stacked body has a first semiconductor layer and a second semiconductor layer provided on the first semiconductor layer. The plasma processing is performed on a surface of the stacked body where the second semiconductor layer is exposed such that the second semiconductor layer remains. The first semiconductor layer includes gallium and nitrogen. The second semiconductor layer includes aluminum and nitrogen. The method includes forming a plurality of protrusions by performing wet etching of the surface after the plasma processing is performed. At least a lower portion of the plurality of protrusions is made of the first semiconductor layer.

In general, according to one embodiment, a semiconductor light emitting device includes a first semiconductor layer and a second semiconductor layer. The first semiconductor layer includes gallium and nitrogen. The second semiconductor layer is provided on the first semiconductor layer and includes aluminum and nitrogen. A plurality of protrusions are formed in a surface on the second semiconductor layer side of a stacked body including the first semiconductor layer and the second semiconductor layer. One of the plurality of protrusions has a hexagonal pyramid configuration. A lower portion of the one of the protrusions includes the first semiconductor layer. An upper portion thereof is formed of the second semiconductor layer. An oblique surface thereof is at least one crystal plane selected from the group consisting of the (11-22) plane, the (1-102) plane, the (1-101) plane, the (11-21) plane, and the (1101) plane.

Embodiments of the invention will now be described with reference to the drawings.

First, a first embodiment will be described.

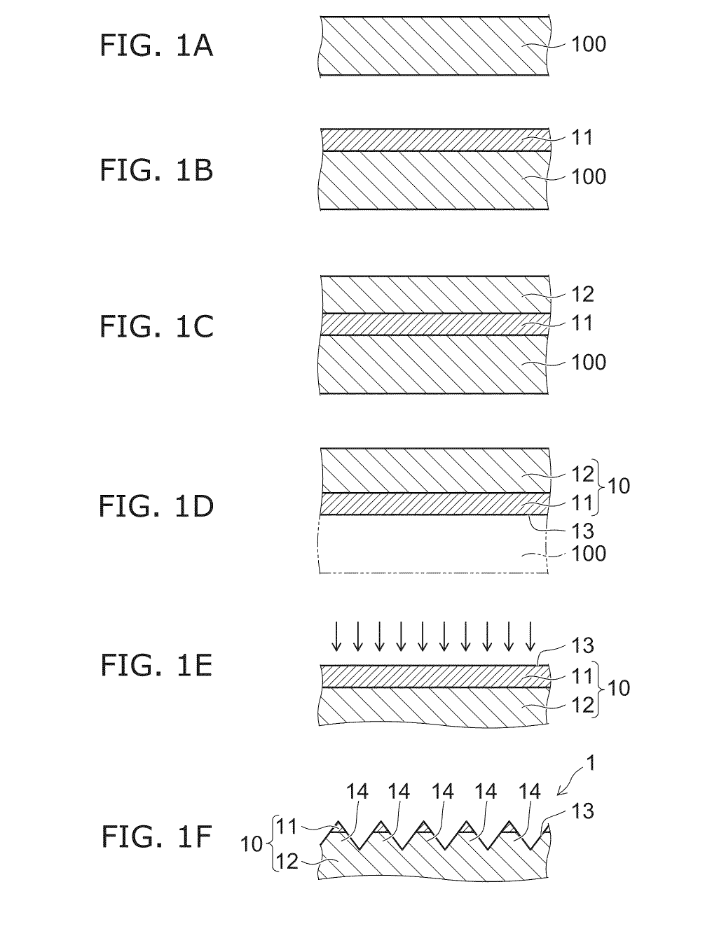

FIGS. 1A to 1F are cross-sectional views of processes, showing a method for manufacturing a semiconductor light emitting device according to the embodiment.

First, as shown in FIG. 1A, a silicon substrate 100 is prepared as a crystal growth substrate. The silicon substrate 100 is, for example, a silicon wafer having a 12-inch diameter.

Then, as shown in FIG. 1B, an aluminum nitride layer (AlN layer) 11 is grown on the silicon substrate 100. The thickness of the AlN layer 11 is set to be, for example, several tens to one hundred and several tens of nanometers. It is sufficient for the AlN layer 11 to be a semiconductor layer including aluminum (Al) and nitrogen (N); and the AlN layer 11 may be formed of a semiconductor including elements other than aluminum and nitrogen such as, for example, AlGaN, etc.

Continuing as shown in FIG. 1C, a gallium nitride layer (GaN layer) 12 is grown on the AlN layer 11. It is sufficient for the GaN layer 12 to be a semiconductor layer including gallium (Ga) and nitrogen. Then, a light emitting unit layer (not shown) that includes a light emitting layer and a pair of clad layers is formed on the GaN layer 12. Also, an n-side electrode (not shown) and a p-side electrode (not shown) are formed to be connected to the light emitting unit layer (not shown).

Then, as shown in FIG. 1D, the silicon substrate 100 is removed. Thereby, a stacked body 10 that includes the AlN layer 11 and the GaN layer 12 is formed; and a surface 13 of the AlN layer 11 on the silicon substrate 100 side is exposed. The surface 13 is the N-polar plane of the AlN layer 11. The surface 13 is not limited to the N-polar plane of the AlN layer 11 and may be a non-polar plane such as the (1100) plane, the (1010) plane, etc., or a semi-polar plane such as the (11-22) plane, etc.

Continuing as shown in FIG. 1E, plasma processing of the surface 13 of the stacked body 10 is performed. The plasma includes, for example, oxygen (O) plasma, sulfur hexafluoride (SF₆) plasma, or argon (Ar) plasma. However, the type of the plasma is not limited thereto. Thereby, reverse sputtering of the surface 13 of the AlN layer 11 is performed. In the reverse sputtering, the etching rate is set to be not more than 10 nm/minute; and the processing time is set to be about 10 minutes. In the plasma processing, the AlN layer 11 remains on the entire surface without being completely removed.

Then, as shown in FIG. 1F, wet etching of the surface 13 of the stacked body 10 is performed using an alkaline aqueous solution. The alkaline aqueous solution includes, for example, a potassium hydroxide (KOH) aqueous solution or a trimethylphenylammonium hydroxide (TMAH (tetra methyl ammonium hydroxide)) aqueous solution. Thereby, the AlN layer 11 and the GaN layer 12 are etched from the surface 13 side and are selectively removed. As a result, many protrusions 14 are formed in hexagonal pyramid configurations in the surface 13 of the stacked body 10. Thereby, the semiconductor light emitting device 1 according to the embodiment is manufactured.

The configuration of the semiconductor light emitting device 1 thus manufactured will now be described.

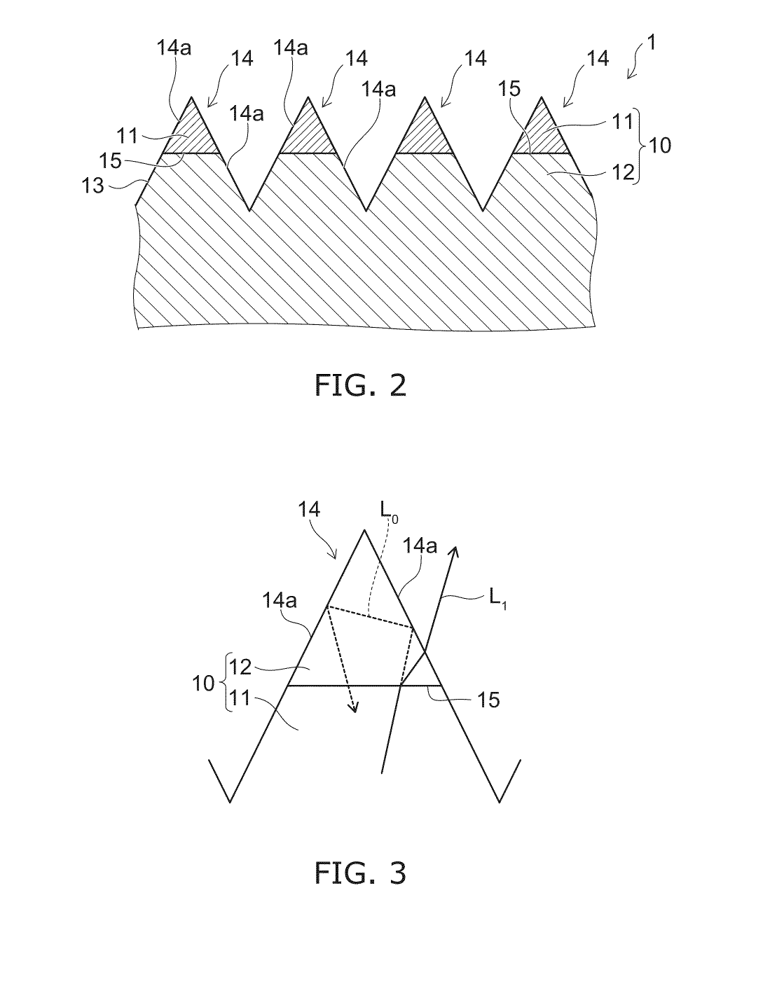

FIG. 2 is a cross-sectional view showing the semiconductor light emitting device according to the embodiment.

As shown in FIG. 2, a light emitting unit layer (not shown) that includes a light emitting layer and a pair of clad layers is provided in the semiconductor light emitting device 1 according to the embodiment; and the n-side electrode (not shown) and the p-side electrode (not shown) are connected to the light emitting unit layer. The GaN layer 12 is provided on the light emitting unit layer; and the AlN layer 11 is provided on the GaN layer 12. Thereby, the stacked body 10, in which the light emitting unit layer, the GaN layer 12, and the AlN layer 11 are stacked, is formed.

Many protrusions 14 having hexagonal pyramid configurations are formed in the surface 13 of the stacked body 10 on the AlN layer 11 side. An oblique surface 14a of the protrusion 14 is at least one crystal plane selected from the group consisting of the (11-22) plane, the (1-102) plane, the (1-101) plane, the (11-21) plane, and the (1101) plane of GaN and AlN. The (11-21) plane described above is the crystal plane of Formula 1 recited below. The other planes are similarly notated.

(11 2̅1) [Formula 1]

In each of the protrusions 14, the lower portion includes the GaN layer 12; and the upper portion includes the AlN layer 11. Therefore, in each of the protrusions 14, an interface 15 exists between the lower portion and the upper portion. Although there is a possibility that the height of the apex of the protrusion 14 and the size of the protrusion 14 may fluctuate in the embodiment as described below, the fluctuation is not shown in FIG. 1F and FIG. 2.

Effects of the embodiment will now be described. In the embodiment, the AlN layer 11 is formed on the silicon substrate 100 in the process shown in FIG. 1B. Thereby, the formation of a solid solution between the silicon substrate 100 and the GaN layer 12 can be suppressed even in the case where the GaN layer 12 is formed in the process shown in FIG. 1C. As a result, the silicon substrate 100, which is less expensive and can easily have a large diameter compared to a sapphire substrate, can be used as the crystal growth substrate.

Also, in the embodiment, plasma processing of the AlN layer 11 is performed in the process shown in FIG. 1E. Thereby, the AlN layer 11 can be etched by being caused to contact an alkaline aqueous solution in the process shown in FIG. 1F; and therefore, the GaN layer 12 also can be etched. As a result, many protrusions 14 can be formed in the surface 13 of the stacked body 10. Because many protrusions 14 are formed in the surface 13, the semiconductor light emitting device 1 has a high light extraction efficiency. Further, by forming the protrusions 14 by wet etching, the costs can be lower than in the case where the protrusions 14 are formed by dry etching. If the plasma processing of the AlN layer 11 is not performed, the AlN layer 11 substantially is not etched and the protrusions 14 are not formed when the AlN layer 11 is caused to contact the alkaline aqueous solution.

In the plasma processing shown in FIG. 1E, the AlN layer 11 remains and is not completely removed. Therefore, compared to plasma processing that is performed to remove the AlN layer 11, the output can be low; the processing time can be reduced; and the type of the plasma is not constrained. Accordingly, the cost of the plasma processing can be reduced. Conversely, in the case where the plasma processing that is performed to remove the AlN layer 11 is performed, the process costs increase because it is necessary to perform processing at a high output for a long period of time using a designated gas.

Although it is not necessarily clear why the wet etching of the AlN layer 11 is possible by performing the plasma processing of the AlN layer 11, the plasma processing introduces dislocations and micro cracks to the AlN layer 11; and it is inferred that the etching progresses with the dislocations and micro cracks as starting points. The embodiment also is useful as a method for providing uniform etching by eliminating the nonuniformity of the etching rate caused by the composition when etching the structural body made of the Group III nitride semiconductors. The embodiment also is applicable to InN, a mixed crystal of InN and GaN, and a mixed crystal of InN and AlN.

Also, according to the embodiment, because the interface 15 exists inside the protrusion 14, the light refracts when passing through the interface 15. Thereby, the light extraction efficiency increases.

FIG. 3 shows the optical path inside the semiconductor light emitting device according to the embodiment.

As shown in FIG. 3, if the interface 15 does not exist, the light that propagates through the stacked body 10 includes light that undesirably undergoes an internal reflection at the oblique surface 14a of the protrusion 14 and is not emitted to the outside as illustrated by an optical path L₀ in FIG. 3. However, as illustrated by an optical path L₁ in FIG. 3, by providing the interface 15, the light that is incident on the interface 15 is refracted at the interface 15; the incident angle with the oblique surface 14a decreases; and the light is emitted to the outside without undergoing the internal reflection at the oblique surface 14a. Thus, a portion of the light that undesirably undergoes the internal reflection inside the protrusion 14 and is not extracted to the outside if no interface 15 exists can be extracted outside the protrusion 14 by disposing the interface 15 inside the protrusion 14. As a result, the light extraction efficiency of the semiconductor light emitting device 1 increases.

A modification of the first embodiment will now be described.

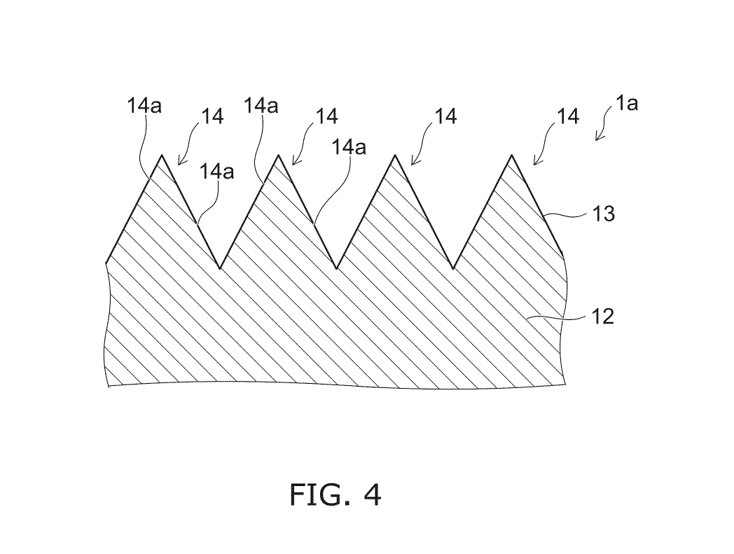

FIG. 4 is a cross-sectional view showing a semiconductor light emitting device according to the modification.

In the semiconductor light emitting device 1a according to the modification as shown in FIG. 4, the AlN layer 11 does not remain; and the entire protrusion 14 includes the GaN layer 12. Such a semiconductor light emitting device 1a can be manufactured by continuing the wet etching of the process shown in FIG. 1F until the AlN layer 11 is completely removed.

Otherwise, the configuration and the manufacturing method of the modification are similar to those of the first embodiment described above. Further, the effects of the modification other than the effect of providing the interface 15 inside the protrusion 14 are similar to those of the first embodiment described above.

A second embodiment will now be described.

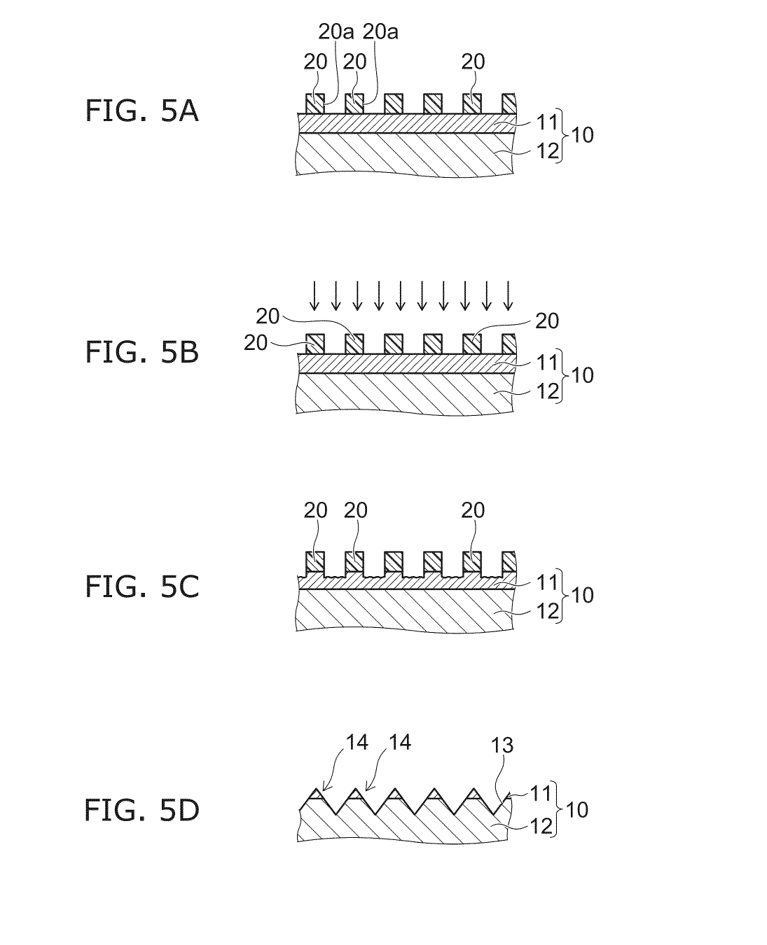

FIGS. 5A to 5D are block diagrams showing a method for manufacturing the semiconductor light emitting device according to the embodiment.

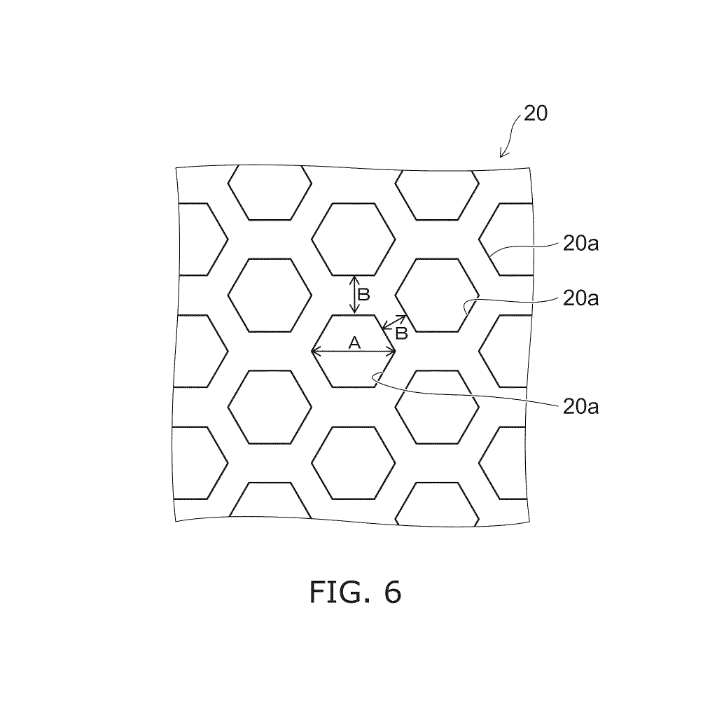

FIG. 6 is a plan view showing a resist mask that is formed in the embodiment.

First, similarly to the first embodiment described above, the processes shown in FIGS. 1A to 1D are implemented.

Then, as shown in FIG. 5A, a resist film is formed on the surface 13 of the stacked body 10 and patterned by using lithography to expose and develop the resist film. Thereby, a resist mask 20 is formed on the surface 13.

As shown in FIG. 6, a pattern is formed in the resist mask 20; the pattern includes, for example, an arrangement in which a regular hexagon is the basic unit; and, for example, an opening 20a having a regular hexagonal configuration is arranged with a constant period along straight lines that are angled 120° from each other. Although the pattern of the resist mask 20 is not limited thereto, it is favorable for the pattern of the resist mask 20 to be a periodic pattern. For example, as described below in the second test example, the configuration of the opening 20a may be a circle or another configuration. In the example shown in FIG. 6, a maximum diameter A of the opening 20a is set to be not more than 1500 nm; and a distance B between the openings 20a is set to be not more than 1500 nm.

Then, as shown in FIG. 5B, plasma processing is performed through the resist mask 20. The conditions of the plasma processing are set to be similar to the conditions of the plasma processing shown in FIG. 1E. Thereby, the region of the surface 13 not covered with the resist mask 20 is exposed to the plasma.

Continuing as shown in FIG. 5C, wet etching using an alkaline aqueous solution is performed. Thereby, first, the portion of the AlN layer 11 not covered with the resist mask 20 is etched. When the AlN layer 11 is pierced locally, the GaN layer 12 under the AlN layer 11 also starts to be etched. On the other hand, the resist mask 20 also is dissolved by the alkaline aqueous solution; and the sizes of the patterns of the resist mask 20 are reduced. Thus, the etching in the vertical direction of the stacked body 10 progresses in parallel with the reduction in the horizontal direction of the sizes of the patterns of the resist mask 20.

As a result, when the alkali treatment ends as shown in FIG. 5D, the resist mask 20 disappears; and many protrusions 14 having hexagonal pyramid configurations are formed in the surface 13 of the stacked body 10. Thereby, the semiconductor light emitting device 2 according to the embodiment is manufactured. At this time, the arrangement period of the protrusions 14 has a period corresponding to the arrangement period of the pattern of the resist mask 20. By the protrusions 14 being arranged at a constant period, the size of the protrusion 14 also can be uniform. As a result, the protrusions 14 are formed in the surface 13 to be periodically arranged with a uniform size.

The configuration of the semiconductor light emitting device 2 thus manufactured will now be described.

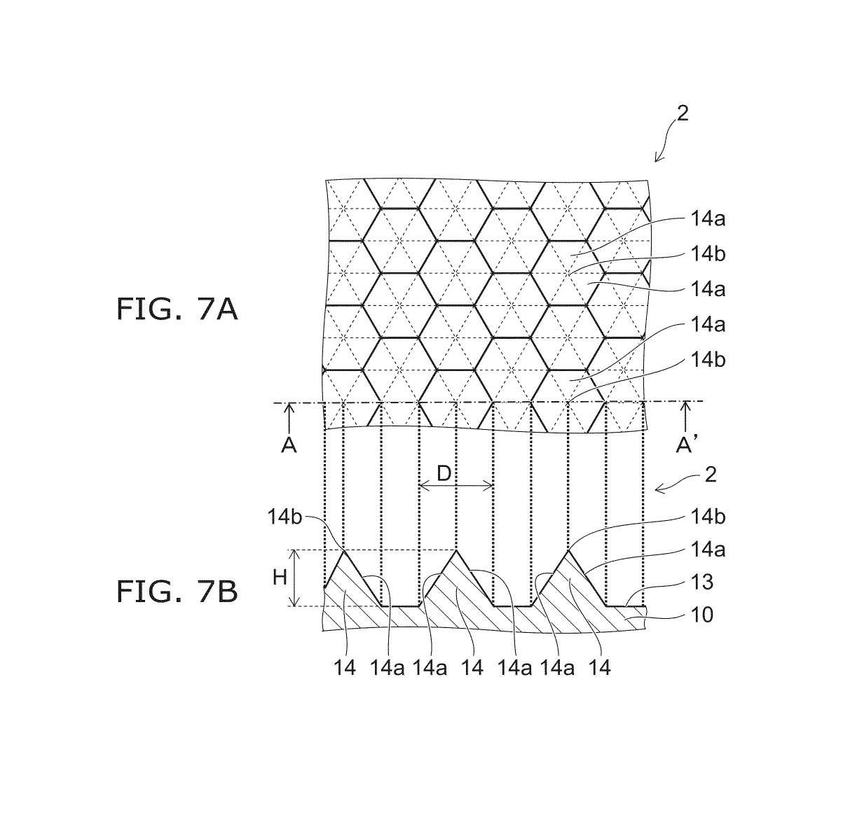

FIG. 7A is a plan view showing the semiconductor light emitting device according to the embodiment; and FIG. 7B is a cross-sectional view along line A-A′ of FIG. 7A.

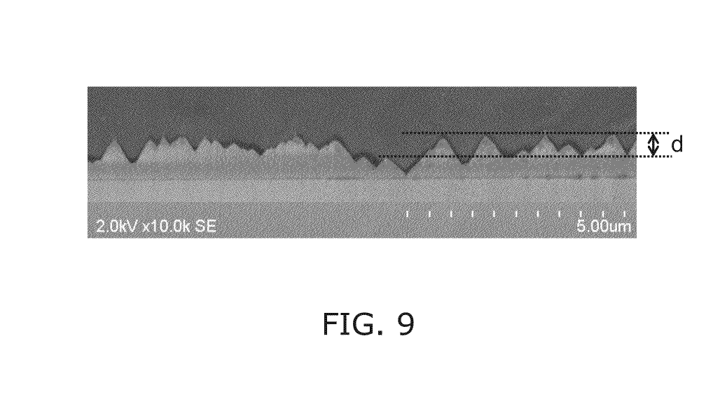

In the semiconductor light emitting device 2 according to the embodiment as shown in FIGS. 7A and 7B, many protrusions 14 are formed in the surface 13 of the stacked body 10. Although the interface 15 is formed inside each of the protrusions 14, the interface 15 is not shown in FIGS. 7A and 7B. As described above, the protrusions 14 are arranged periodically; and the sizes of the protrusions 14 are uniform. Specifically, the difference d (referring to FIG. 9) between the height of the highest apex 14b and the height of the lowest apex 14b of the protrusions 14 in a range having a length of 10 μm of a cross section of the stacked body 10 is not more than 100 nm. The difference d is an indicator that indicates the fluctuation of the height of the protrusions 14.

The cross section of the stacked body 10 can be viewed by, for example, a SEM (scanning electron microscope). The light extraction efficiency can be increased by forming the protrusions 14 uniformly. For each of the protrusions 14, a height H is, for example, 200 to 2000 nm; and a maximum diameter D is, for example, 200 to 2000 nm.

Because the resist mask 20 is formed in the process shown in FIG. 5A and the plasma processing is performed through the resist mask 20 in the process shown in FIG. 5B according to the embodiment, the protrusions 14 are formed in an arrangement that reflects the arrangement of the pattern of the resist mask 20 when the wet etching is performed in the processes shown in FIGS. 5C and 5D. Thereby, the protrusions 14 can be formed uniformly and periodically by forming the periodic pattern in the resist mask 20. As a result, the light extraction efficiency of the semiconductor light emitting device 2 increases. In particular, it is favorable for the value of the difference d described above to be not more than 100 nm because the light extraction efficiency is stable and high.

Otherwise, the manufacturing method, the configuration, and the effects of the embodiment are similar to those of the first embodiment described above. In the embodiment as well, as in the modification of the first embodiment described above, the entire protrusion 14 may be formed of the GaN layer 12.

Test examples that illustrate the effects of the embodiments described above will now be described.

The first test example recited below illustrates the effects of the first embodiment described above; and the second test example and the third test example illustrate the effects of the second embodiment described above.

### FIRST TEST EXAMPLE

For the first test example, five samples were made; different processing was performed respectively on the samples; and it was evaluated whether or not the protrusions were formed in the surface. The results are shown in Table 1.

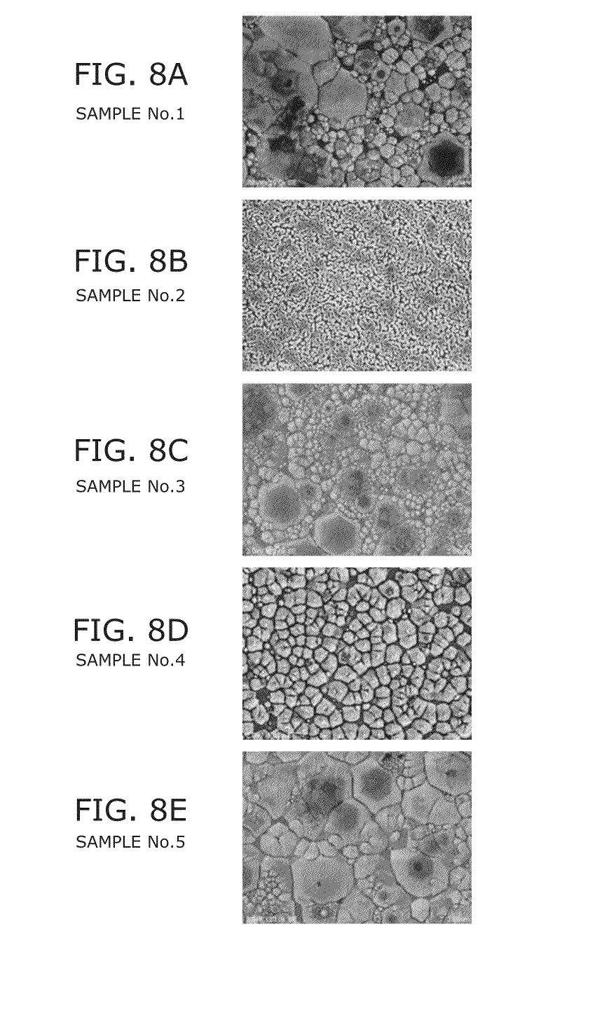

FIGS. 8A to 8E are surface SEM photographs showing each of the samples of the test example.

FIG. 9 is a cross section SEM photograph showing sample No. 3.

TABLE 1

| | | Layer | Plasma | Alkali | |
|---|---|---|---|---|---|
| Sample | Type | structure | processing | treatment | Protrusions |
| No. 1 | Comparative | GaN | None | Yes | Yes |
| | example | | | | |
| No. 2 | Comparative | GaN/AlN | None | Yes | None |
| | example | | | | |
| No. 3 | Example | GaN/AlN | Ar | Yes | Yes |
| No. 4 | Example | GaN/AlN | O | Yes | Yes |
| No. 5 | Example | GaN/AlN | SF₆ | Yes | Yes |

The “examples” shown in Table 1 are examples of the first embodiment described above. The “plasma processing” shown in Table 1 was performed at conditions such that the AlN layer remained on the entire surface. The “alkali treatment” shown in Table 1 is wet etching using a potassium hydroxide (KOH) aqueous solution having a concentration of 1 mole/liter (mol/L) as the etchant at a temperature of 80° C. for 8 minutes. The determination of yes/none for the protrusions was performed by viewing the surface using SEM after the alkali treatment.

In sample No. 1 as shown in Table 1, the layer structure of the stacked body was a single-layer GaN layer. The outermost surface of the GaN layer was the N-polar plane. Then, the alkali treatment described above was performed without performing plasma processing. As a result, as shown in FIG. 8A, many protrusions having hexagonal pyramid configurations were formed in the surface of the stacked body. However, because the AlN layer was not formed in sample No. 1, a solid solution undesirably formed between the silicon substrate and the GaN layer when the GaN layer was directly formed on the silicon substrate. Therefore, as the crystal growth substrate, it is necessary to use a substrate other than a silicon substrate, e.g., a sapphire substrate that is more expensive; and the cost increases.

For sample No. 2, the layer structure of the stacked body was a two-layer structure of a GaN layer and an AlN layer (hereinbelow, notated as “GaN/AlN”); and the outermost surface was the N-polar plane of the AlN layer. Then, the alkali treatment described above was performed without performing plasma processing. As a result, as shown in FIG. 8B, the AlN layer substantially was not etched; and protrusions having hexagonal pyramid configurations were not formed in the surface of the stacked body. For sample No. 2, the etching rate of the AlN layer for the potassium hydroxide aqueous solution was not more than 1/100 of the etching rate of the GaN layer.

For sample No. 3, the layer structure of the stacked body was a GaN/AlN two-layer structure; and the outermost surface was the N-polar plane of the AlN layer. Then, plasma processing was performed using argon (Ar). The conditions of the plasma processing were a flow rate of argon gas of 20 sccm and an output of 500 W for 10 minutes. Subsequently, the alkali treatment described above was performed. As a result, as shown in FIGS. 8C and FIG. 9, protrusions having hexagonal pyramid configurations were formed in the surface of the stacked body. For sample No. 3, the etching rate of the AlN layer for the potassium hydroxide aqueous solution was not less than 1/5 of the etching rate of the GaN layer. As shown in FIG. 9, for sample No. 3, the difference d between the height of the highest apex and the height of the lowest apex of the protrusions in a range having a length of 10 μm of a cross section of the stacked body was greater than 100 nm.

For sample No. 4, similarly to sample No. 3, the structure of the stacked body was a two-layer structure of GaN/AlN. Then, plasma processing using oxygen was performed; and subsequently, the alkali treatment described above was performed. As a result, as shown in FIG. 8D, protrusions having hexagonal pyramid configurations were formed in the surface of the stacked body.

For sample No. 5 as well, similarly to samples No. 3 and No. 4, the structure of the stacked body was a two-layer structure of GaN/AlN. Then, plasma processing using sulfur hexafluoride (SF₆) was performed; and subsequently, the alkali treatment described above was performed. As a result, as shown in FIG. 8E, protrusions having hexagonal pyramid configurations were formed in the surface of the stacked body.

Thus, according to the first test example, the protrusions were formed in the processing surface for samples No. 3, No. 4, and No. 5 for which the alkali treatment was performed after performing the plasma processing. On the other hand, the protrusions were not formed in sample No. 2 for which the alkali treatment was performed without performing the plasma processing. Even for sample No. 2 for which the plasma processing was not performed, the protrusions can be formed in the surface if the alkali treatment is performed for an exceedingly long period of time. However, not only is such a method industrially unrealistic, but the regions where the protrusions are formed and the regions where the protrusions are not formed are undesirably distributed in patches. Moreover, in the regions where the protrusions are formed, the AlN layer undesirably remains in columnar configurations; and the protrusions do not have hexagonal pyramid configurations. As a result, the light extraction efficiency decreases. On the other hand, even though the protrusions were formed by performing the alkali treatment without performing plasma processing for sample No. 1 in which the AlN layer was not formed, sample No. 1 has the constraint that a silicon substrate cannot be used as the crystal growth substrate.

### SECOND TEST EXAMPLE

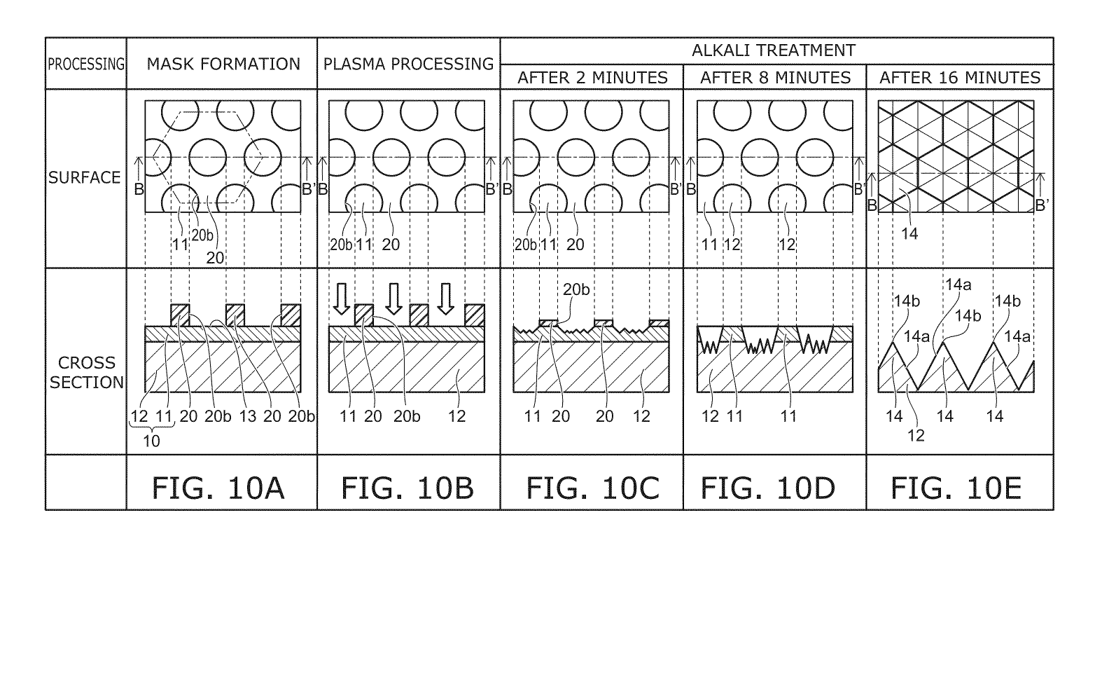

FIGS. 10A to 10E show states of a sample of a second test example at each of the stages. The upper level shows the surface of the sample; and the lower level shows the cross section of the sample.

In FIGS. 10A to 10E, the lower level shows the cross section along line B-B′ of the upper level.

Reference numerals similar to those of the second embodiment described above are used in FIGS. 10A to 10E.

First, as shown in FIG. 10A, the stacked body 10, in which the AlN layer 11 was formed on the GaN layer 12, was formed; and the resist mask 20 was formed on the surface 13 of the stacked body 10. The surface 13 was the N-polar plane of the AlN layer. Circular openings 20b were periodically arranged in the resist mask 20 such that line segments connecting the centers of the openings 20b formed a regular hexagon as viewed from above.

Then, as shown in FIG. 10B, plasma processing was performed using argon plasma. The processing conditions were similar to those of sample No. 3 of the first test example. Thereby, although reverse etching of the portions of the AlN layer 11 exposed inside the openings 20b of the resist mask 20 was performed by the portions being exposed to the plasma, the thickness of the AlN layer 11 substantially did not change.

Then, as shown in FIGS. 10C to 10E, alkali treatment was performed. Specifically, wet etching was performed using a TMAH aqueous solution having a concentration of 25% at a temperature of 80° C.

After 2 minutes elapsed from starting the alkali treatment as shown in FIG. 10C, the resist mask 20 became thinner. Also, the portions of the AlN layer 11 disposed in the regions directly under the openings 20b were etched to form a fine unevenness.

After 8 minutes elapsed from starting the alkali treatment as shown in FIG. 10D, the resist mask 20 substantially disappeared. Also, the AlN layer 11 was pierced and the GaN layer 12 had started to be etched in the regions of the resist mask 20 corresponding to the openings 20b. At this time, the etching of the AlN layer 11 and the GaN layer 12 was anisotropic; and the oblique surfaces of hexagonal columns had started to form.

After 16 minutes elapsed from starting the alkali treatment as shown in FIG. 10E, the AlN layer 11 had substantially disappeared; and the protrusions 14 having hexagonal pyramid configurations had formed in the GaN layer 12. The apexes 14b of the protrusions 14 were positioned inside the regions covered with the resist mask 20; and therefore, the form and period of arrangement of the protrusions 14 correspond to the form and period of arrangement of the openings 20b of the resist mask 20. Further, the difference d (referring to FIG. 9) between the height of the highest apex 14b and the height of the lowest apex 14b of the protrusions 14 in a range having a length of 10 μm of a cross section of the stacked body was not more than 100 nm. Also, according to the test example, the light extraction efficiency of the semiconductor light emitting device after completion was about 10% higher than that of the case where the resist mask 20 was not formed.

### THIRD TEST EXAMPLE

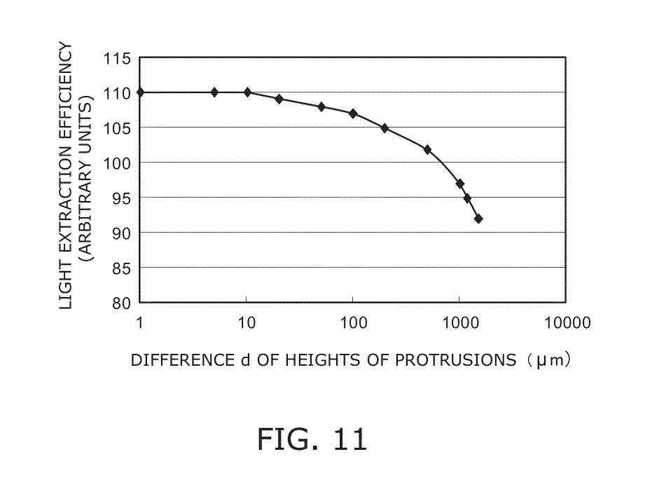

In a third test example, multiple samples having different values of the difference d described above were made; and the light extraction efficiencies of the samples were measured. The measurement results are shown in FIG. 11.

FIG. 11 is a graph showing the effects of the fluctuation of the height of the protrusions on the light extraction efficiency of the semiconductor light emitting device, where the horizontal axis is the value of the difference d, and the vertical axis is the light extraction efficiency.

As shown in FIG. 11, the light extraction efficiency increases as the value of the difference d decreases. In particular, the light extraction efficiency is stable and high when the difference d is not more than 100 nm.

According to the embodiments described above, a low-cost semiconductor light emitting device having a high light extraction efficiency and a method for manufacturing the device can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing a semiconductor light emitting device, comprising:
performing plasma processing of a stacked body including a first semiconductor layer and a second semiconductor layer provided on the first semiconductor layer, the plasma processing being performed on a surface of the stacked body where the second semiconductor layer is exposed such that the second semiconductor layer remains, the first semiconductor layer including gallium and nitrogen, the second semiconductor layer including aluminum and nitrogen; and
forming a plurality of protrusions by performing wet etching of the surface after the plasma processing is performed, at least a lower portion of the plurality of protrusions being made of the first semiconductor layer.

2. The method according to claim 1, further comprising forming a mask on the second semiconductor layer, a pattern that is periodic being formed in the mask,
the plasma processing being performed through the mask.

3. The method according to claim 1, further comprising:
forming the second semiconductor layer on a silicon substrate;
forming the first semiconductor layer on the second semiconductor layer; and
removing the silicon substrate.

4. The method according to claim 1, wherein the plasma processing is performed using oxygen plasma, sulfur hexafluoride plasma, or argon plasma.

5. The method according to claim 1, wherein the wet etching is performed using an alkaline aqueous solution.

6. The method according to claim 5, wherein the alkaline aqueous solution includes a potassium hydroxide aqueous solution or a trimethylphenylammonium hydroxide aqueous solution.

7. The method according to claim 1, wherein the first semiconductor layer is formed of GaN, and the second semiconductor layer is formed of AlN.

8. A method for manufacturing a semiconductor light emitting device, comprising:
forming an AlN layer on a silicon substrate;
forming a GaN layer on the AlN layer;
removing the silicon substrate;
forming a mask on a surface where the AlN layer is exposed by the removing of the silicon substrate, a pattern that is periodic being formed in the mask;
performing, through the mask, plasma processing of the surface where the AlN layer is exposed such that the AlN layer remains; and
forming a plurality of protrusions by using an alkaline aqueous solution to perform wet etching of the surface after the plasma processing is performed, at least a lower portion of the plurality of protrusions being made of the GaN layer.

9. A semiconductor light emitting device, comprising:
a first semiconductor layer including gallium and nitrogen; and
a second semiconductor layer provided on the first semiconductor layer, the second semiconductor layer including aluminum and nitrogen,
a plurality of protrusions being formed in a surface on the second semiconductor layer side of a stacked body including the first semiconductor layer and the second semiconductor layer, one of the plurality of protrusions having a hexagonal pyramid configuration having a lower portion including the first semiconductor layer, an upper portion formed of the second semiconductor layer, and an oblique surface being at least one crystal plane selected from the group consisting of the (11-22) plane, the (1-102) plane, the (1-101) plane, the (11-21) plane, and the (1101) plane.

10. The device according to claim 9, wherein the difference between the height of the highest apex and the height of the lowest apex of the protrusions in a range having a length of 10 μm of a cross section of the stacked body is not more than 100 nm.
